(19) United States
(12) Patent Application Publication
(10) Pub. No.: US 2014/0083350 A1
(43) Pub. Date: Mar. 27, 2014

(54) METHOD OF PRODUCING GROUP III-V COMPOUND SEMICONDUCTOR SINGLE CRYSTAL

(71) Applicant: HITACHI METALS, LTD., Tokyo (JP)

(72) Inventor: Takeshi KIMURA, Hitachi-shi (JP)

(21) Appl. No.: 14/020,594

(22) Filed: Sep. 6, 2013

(30) Foreign Application Priority Data
Sep. 27, 2012 (JP) 2012-214084

(51) Int. Cl. C30B 15/04

(52) U.S. Cl. CPC C30B 15/04
USPC 117/19

(57) ABSTRACT

Provided is a method of producing a group III-V compound, comprising: producing a raw material by housing a group III-V compound semiconductor crystal containing group III element and group V element and an impurity in a crucible, and heating and melting the group III-V compound semiconductor crystal in a state that a surface of the group III-V compound semiconductor crystal to an atmosphere in the crucible; growing the group III-V compound semiconductor single crystal by heating the raw material and an encapsulant by adding the encapsulant into the crucible in which the raw material is housed, and making a seed crystal in contact with a melt of the raw material with a liquid surface covered by the encapsulant in a liquid state, and lifting the seed crystal.

### BACKGROUND

1. Technical Field

The present application is based on Japanese Patent Application No. 2012-214084 filed on Sep. 27, 2012, the entire contents of which are hereby incorporated by reference.

The present invention relates to a method of producing a group III-V compound semiconductor single crystal, and particularly relates to the method of producing a group III-V compound semiconductor single crystal using a group III-V compound semiconductor crystal containing impurities.

2. Description of Related Art

For example, a Liquid Encapsulated Czochralski method (LEC) can be given as one of the methods of producing a group III-V compound semiconductor single crystal used as a substrate, etc., of a semiconductor device. In the LEC method, a raw material and an encapsulant are housed and heated in a crucible, and a seed crystal is brought into contact with a melt of the raw material with a liquid surface covered by the encapsulant in a liquid state, to thereby cause a crystal growth while lifting the seed crystal. At this time, there is also a case that an impurity such as carbon (C), etc., is added for example. In the LEC method, a specific number of defective product is generated, like in a case that a semiconductor crystal is polycrystallized.

Therefore, for example patent document 1 discloses a technique of recovering Ga and As by distilling and separating gallium chloride (GaCl₃) and arsenic chloride (AsCl₃) from a gallium (Ga)-containing scrap generated through the LEC method, etc. Thus, refined Ga and As with high purity can be reused as the raw material of a semiconductor single crystal.
Patent document 1: Examined Patent Publication No. 1995-17374

However, it is mainly Ga that is recovered by a conventional technique like the patent document 1, and a majority of As is disposed. Further, refinement of Ga and As using the distillation and separation requires a considerable cost and man-hours.

It can be considered that the semiconductor crystal being the defective product is reused as it is as the raw material by the LED method, etc., for example. However, as described above, the impurity added at the time of production is contained in the semiconductor crystal, and there is sometimes a variation in concentrations of the impurity, in each defective product. For example, when the semiconductor single crystal is produced using such a defective product by the LED method, etc., it is difficult to stably control the impurity to a specific concentration in the semiconductor single crystal.

An object of the present invention is to provide a method of producing an inexpensive and simple group III-V compound semiconductor single crystal that can be used as a raw material even in a case of a semiconductor crystal containing an impurity.

### SUMMARY OF THE INVENTION

According to an aspect of the present invention, there is provided a method of producing a group III-V compound semiconductor single crystal, using a Liquid Encapsulated Czochralski method, including:

producing a raw material by housing a group III-V compound semiconductor crystal containing group III element and group V element and an impurity in a crucible, and heating and melting the group III-V compound semiconductor crystal in a state that a surface of the group III-V compound semiconductor crystal to an atmosphere in the crucible;

growing the group III-V compound semiconductor single crystal by heating the raw material and an encapsulant by adding the encapsulant into the crucible in which the raw material is housed, and making a seed crystal in contact with a melt of the raw material with a liquid surface covered by the encapsulant in a liquid state, and lifting the seed crystal.

In producing the raw material, preferably an inside of the crucible is set in an inert gas atmosphere of not less than a steam pressure of the group V element and not more than the steam pressure of a gas component containing the impurity.

In producing the raw material, preferably an inside of the crucible is set in an inert gas atmosphere of a pressure of 5 MPa or more and 8 MPa or less.

In producing the raw material, preferably an upper portion of the crucible is covered by a lid.

Preferably, the impurity is composed of an element that controls conductivity of a group III-V compound semiconductor.

Preferably, the impurity is C.

Preferably, in growing the group III-V compound semiconductor single crystal,

an impurity of the same kind as the above impurity is incorporated into the raw material through the encapsulant that covers a liquid surface of the raw material, to thereby grow a semi-insulating group III-V compound semiconductor single crystal containing the impurity, and

when incorporating the impurity into the raw material,

incorporation of the impurity into the raw material is accelerated by the encapsulant.

Preferably, the group III element is at least any one of Ga, In, and Al, and the group V element is at least any one of As, P, and N.

According to the present invention, there is provided an inexpensive and simple method of producing a group III-V compound semiconductor single crystal that can be used as a raw material even in a case of a semiconductor crystal in which an impurity is contained.

### BRIEF DESCRIPTION OF THE DRAWINGS

FIG. 1A is a schematic view of a semiconductor single crystal producing device according to an embodiment of the present invention, wherein an upper portion of a crucible provided in the semiconductor single crystal producing device is opened.

FIG. 1B is a view showing a state that the upper portion of the crucible provided in the semiconductor single crystal producing device shown in FIG. 1A, is covered by a lid.

FIG. 2 is a schematic view showing each kind of reaction that occurs on a B₂O₃—GaAs melt interface in the crucible, in the method of producing a group III-V compound semiconductor single crystal according to an embodiment of the present invention.

FIG. 3 is a graph showing a carbon concentration in each lot of a semi-insulating GaAs single crystal according to an example of the present invention and a comparative example.

### DETAILED DESCRIPTION OF THE INVENTION

### Knowledge Obtained by Inventors of the Present Invention

As described above, a method of inexpensively and easily reusing a defective product generated through an LEC method for example, is not known. Inventors of the present invention attempt to produce a semiconductor single crystal by the LEC method, by using the group III-V compound semiconductor crystal being the defective product as it is as a raw material.

An impurity such as C that imparts semi-insulating property to a semiconductor for example, is sometimes added to the above-mentioned semiconductor crystal being the defective product. Therefore, in order to control the impurity to a specific concentration in the semiconductor single crystal produced from the defective product, the concentration of the impurity in the defective product is previously specified, and the impurity of a quantity after subtracting the impurity in the defective product must be added as needed.

However, there is a large variation in the concentration of the impurity in each defective product, and it is difficult to obtain a stable specific concentration of the impurity in the semiconductor single crystal obtained finally. Further, even if an adjustment is made in consideration of the concentration of the impurity in the defective product, the concentration of the final impurity is not set to the specific concentration in some cases, and a sufficient controllability cannot be obtained.

In order to improve the controllability of the concentration of the impurity, strenuous efforts are made by the inventors of the present invention. As a result, it is found that the semiconductor single crystal with the impurity set to the specific concentration can be stably produced, irrespective of the concentration of the impurity in the semiconductor crystal, by using a specific heating method when housing, heating, and melting the semiconductor crystal being the raw material in the crucible.

The present invention is based on the above-mentioned knowledge found by the inventors of the present invention.

### AN EMBODIMENT OF THE PRESENT INVENTION

### (1) A Semiconductor Single Crystal Producing Device

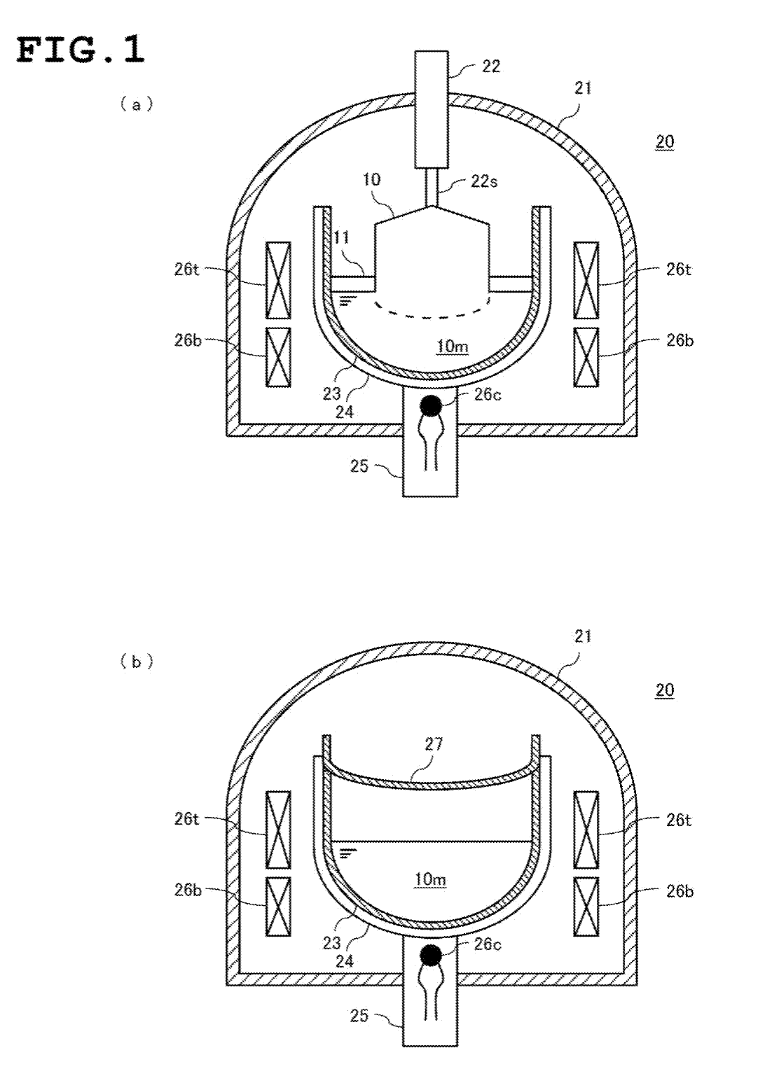

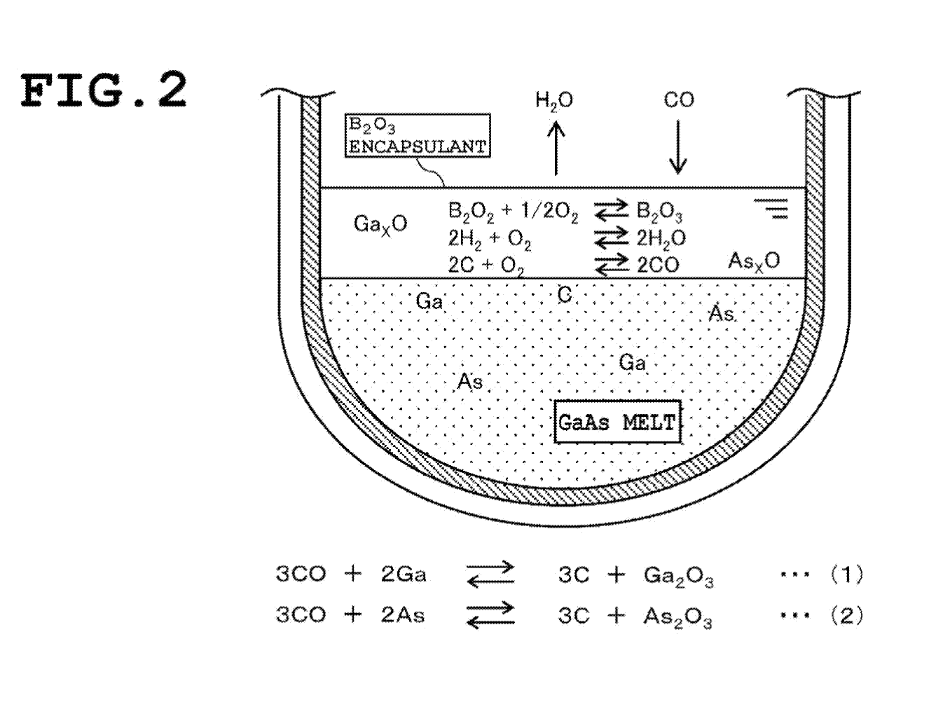

First, using FIG. 1A and FIG. 1B, explanation is given for a semiconductor single crystal producing device capable of executing the method of producing a group III-V compound semiconductor single crystal according to an embodiment of the present invention. FIG. 1A is a schematic view of a semiconductor single crystal producing device 20 according to this embodiment, showing an open state of an upper portion of a crucible provided in the semiconductor single crystal producing device 20. FIG. 1B is a view showing a state that the upper portion of the crucible 23 provided in the semiconductor single crystal producing device 20 shown in FIG. 1A is covered by a lid 27.

As shown in FIG. 1A, the semiconductor single crystal producing device 20 includes a high-pressure vessel 21 having a pressure-resistance configured to introduce specific gas. A cylindrical crucible 23 with an upper portion opened and a lower portion closed for example, is provided in approximately a center part in the high-pressure vessel 21. The crucible 23 is made of thermal decomposition boron nitride (PBN: Pyrolytic Boron Nitride), etc., having excellent heat resistant property for example. The crucible 23 is configured to house a raw material 10m of the semiconductor single crystal 10 and an encapsulant 11, etc.

A cylindrical lifting shaft (upper shaft) 22 used for lifting the semiconductor single crystal 10, is inserted into the high-pressure vessel 21 from above in the center of the high-pressure vessel 21. A lower edge of the lifting shaft 22 is configured to attach a seed crystal 22s thereto, and is configured to face the crucible 23 in the high-pressure vessel 21. Further, the lifting shaft 22 is configured to be freely rotated and elevated by a rotator and an elevator not shown.

Further, the crucible 23 is supported by a cylindrical pedestal (lower shaft) through a vessel-type susceptor 24 in which the crucible 23 is housed. The pedestal 25 is inserted into the high-pressure vessel 21 concentrically with the lifting shaft 22 from below in the center of the high-pressure vessel 21. Further, the pedestal 25 is configured to be freely rotated and elevated by the rotator and the elevator not shown. The susceptor 24 is made of graphite, etc., for example, and is fixed to an upper edge of the pedestal 25.

Further, in the high-pressure vessel 21, upper heaters 26t and lower heaters 26b for heating the raw material 10m and the encapsulant 11 housed in the crucible, are respectively disposed in an upper position and a lower position of the crucible 23 so as to surround the crucible 23. The upper heaters 26t and the lower heaters 26b are respectively made of graphite, etc., for example. Also, the upper heaters 26t and the lower heaters 26b include a temperature controller (not shown) as a temperature control unit for controlling each temperature. Further, a thermocouple 26c is provided in the upper portion of the pedestal 25, as a temperature detector for detecting the temperature of the raw material 10m and the encapsulant 11 in the crucible 23.

Further, as shown in FIG. 1B, the semiconductor single crystal producing device 20 includes a lid 27 for covering an opened upper portion of the crucible 23 in a state that the lifting shaft 22 is pulled-up for example. The lid 27 is made of PBN, etc., for example.

As described above, a single crystal of the group III-V compound semiconductor such as GaAs, GaP, InAs, and InP, etc., is produced by the semiconductor single crystal producing device 20 having the above-mentioned structure, using a Liquid Encapsulated Czochralski (LEC) method. In the LEC method, a single crystal growth of the group III-V compound semiconductor can be carried out while suppressing a decomposition (dissociation) and evaporation of the V-group element having a high steam pressure such as arsenic (As) and phosphorus (P), etc., by making a state that the encapsulant 11 is set in a liquid state to cover the melt of the raw material 10m.

### (2) A Method of Producing the Group III-V Compound Semiconductor Single Crystal

Explanation is given hereafter for the method of producing a group III-V compound semiconductor single crystal according to an embodiment of the present invention executed by the semiconductor single crystal producing device 20 for example as described above. The method of producing a group III-V compound semiconductor single crystal according to this embodiment, is performed by the LEC method for example.

### [Preparation Step of a Semiconductor Crystal]

In this embodiment, a crystal composed of GaAs as the group III-V compound semiconductor containing gallium (Ga) as the group III element, arsenic (As) as the group V element, and carbon (C) as the impurity for imparting semi-insulating property to the semiconductor, is prepared.

The GaAs crystal corresponds to a defective part of the polycrystal, namely, is a GaAs polycrystal, etc., generated in an ingot of the single crystal in a process of producing the GaAs single crystal by the normal LEC method for example. Specifically, in the normal LEC method, for example a powdered or aggregated raw material containing Ga and As with high purity and the encapsulant are housed in the crucible, which are then heated and melted, and the gas, etc., containing C-element being the impurity is introduced into the crucible and is incorporated into the melt of the source with the liquid surface covered by the encapsulant in the liquid form. Thereafter, the seed crystal is brought into contact with the melt of the raw material, and the crystal growth is caused while lifting the seed crystal.

The GaAs single crystal thus produced is ground by a cylindrical grinding blade so as to be formed into a cylindrical shape, and annealing is applied thereto as needed, so that for example a polycrystalline defective part is cut-out by a band saw, etc. The defective part thus cut-out is further crushed by the band saw, etc., to thereby prepare the GaAs polycrystal.

### [Producing Step of the Raw Material]

In the producing step of the raw material 10m, unlike the normal LEC method, the GaAs polycrystal is heated and melted without charging the encapsulant 11, to thereby produce the raw material 10m.

Namely, the GaAs polycrystal thus obtained is housed in the crucible 23 provided in the semiconductor single crystal producing device 20 for example. Subsequently, an inert gas such as nitrogen (N₂) and argon (Ar), etc., is introduced into the high-pressure vessel 21, and the GaAs polycrystal is heated and melted to 600° C. or more and 700° C. or less by the upper heaters 26t and the lower heaters 26b.

When the GaAs polycrystal is melted, an inside of the crucible is set in an inert gas atmosphere in which for example a pressure is 5 MPa or more and 8 MPa or less, and preferably 6 MPa or more and 8 MPa or less. In this case, as shown in FIG. 1B, the pressure inside of the crucible can easily reach the aforementioned pressure and this pressure can be maintained by making the state that the upper portion of the crucible 23 is covered by the lid 27.

After the melt of the GaAs polycrystal is maintained for a specific time, for one hour for example, heating by the upper heaters 26t and the lower heaters 26t are stopped, to thereby rapidly cool the melt. After stop of the heating, the melt is left to stand for a specific time, for four hours to five hours for example, to thereby solidify the melt.

As described above, the raw material 10m used for producing the group III-V compound semiconductor single crystal of this embodiment is produced.

### [Growing Step of the Semiconductor Single Crystal]

Subsequently, the growing step of the GaAs single crystal being the group III-V compound semiconductor single crystal is performed, using the raw material 10m produced as described above. The growing step of the GaAs single crystal includes “a heating step of the raw material and the encapsulant” and “a lifting step of the semiconductor single crystal” as described later. Also, the growing step of the GaAs single crystal may have “an incorporating step of the impurity” as described later.

### (The Heating Step of the Raw Material and the Encapsulant)

The lid 27 of the upper portion of the crucible 23 is removed, and the encapsulant 11 is added into the coagulated raw material 10m. For example boron trioxide (B₂O₃), etc., is used as the encapsulant 11.

Subsequently, as shown in FIG. 1A, the raw material 10m and the encapsulant 11 are heated in the crucible 23 with the upper portion opened by removing the lid 27. In this case, the inside of the crucible 23 is set in the inert gas atmosphere in which the pressure is the atmospheric pressure or more for example.

The raw material 10m in a coagulated state is melted into the melt, when it is heated and its temperature reaches a melting temperature in the crucible 23. Further, the encapsulant 11 such as B₂O₃, etc., is set in a solid state at a normal temperature for example, and when it is heated and its temperature reaches the melting temperature in the crucible 23, the raw material 10m is melted and set in a liquid state. Since a specific gravity of the encapsulant 11 is smaller than the specific gravity of the melt, the liquid surface of the raw material 10m being the melt is covered by the encapsulant 11.

Thus, by maintaining the inside of the crucible 23 to the atmospheric pressure or more and covering the liquid surface of the raw material 10m by the encapsulant 11 in the liquid state, the decomposition and evaporation of As with high steam pressure from the raw material 10m can be suppressed.

### (The Incorporating Step of the Impurity Element)

Here, a carbon (C) component is incorporated into the raw material 10m so that the produced GaAs single crystal has semi-insulating property.

Specifically, a carbon (C)-containing gas such as carbon monoxide (CO) gas and carbon dioxide (CO₂) gas is introduced into the inert gas atmosphere in the crucible 23, as an impurity element-containing gas in a state that the raw material 10m and the encapsulant 11 are melted.

Thus, the C component in the C-containing gas is incorporated into the melt of the raw material 10m through the encapsulant 11 which covers the liquid surface of the raw material 10m, to thereby obtain the raw material 10m in which C is added as the impurity. At this time, by controlling an introduction amount of the C-containing gas and adjusting a partial pressure of the C-containing gas in the crucible 23, the concentration of the C incorporated into the raw material 10m can be set to the specific concentration.

### (Lifting Step of the Semiconductor Single Crystal)

Subsequently, the seed crystal 22s is brought into contact with the melt of the raw material 10m with the liquid surface covered by the encapsulant 11 in the liquid state, to thereby lift the seed crystal 22s while gradually decreasing the heating temperature by the upper heaters 26t and the lower heaters 26b. Thus, the semiconductor single crystal 10 of the GaAs single crystal, etc., is grown, and is lifted so as to pass through the encapsulant 11.

At this time, with a progress of the crystal growth, the melt of the raw material 10m in the crucible 23 is reduced and the liquid surface is lowered, and a positional relation between the upper heaters 26t and the lower heaters 26b, and the crystal growth interface is changed. Therefore, a reduction amount of the liquid surface of the raw material 10m is calculated from a crystal growth amount, and the elevator is controlled to correct the reduction amount, so that the pedestal 25 is gradually elevated, to thereby adjust a position of the crucible 23. Thus, the liquid surface of the raw material 10m is maintained to be approximately constant, with respect to the upper heaters 26t and the lower heaters 26b. Therefore, the melt of the raw material 10m can be efficiently heated and its temperature can be maintained to approximately a constant temperature.

As described above, the GaAs single crystal is produced as the semi-insulating group III-V compound semiconductor single crystal, using the GaAs polycrystal of the defective part as the raw material.

### [Action in the Producing Method]

Initially, the inventors of the present invention house the encapsulant initially together with the GaAs polycrystal of the defective part being the raw material, and heat and melt the GaAs polycrystal and the encapsulant under the inert gas atmosphere. Then, as described above, a specific amount of C-containing gas is introduced into the crucible so that the concentration of C finally reaches the specific concentration in consideration of the amount of C previously contained in the defective part, so that C is incorporated into the melt.

However, the concentration of C in the GaAs single crystal thus produced does not reach the specific concentration in some cases. Further, there is a variation in the concentration of C which is previously contained in the GaAs polycrystal being the defective part, and therefore under such an influence, there is also the variation generated in the C-concentration in the produced GaAs single crystal in some cases.

As a result of strenuous efforts by the inventors of the present invention, it is found that if the GaAs polycrystal is heated and melted without using the encapsulant, the C-concentration in the GaAs single crystal can be precisely controlled under almost no influence of the C-concentration in the GaAs polycrystal being the raw material.

It can be considered that C initially contained in the GaAs polycrystal is desorbed from the melt of the GaAs polycrystal irrespective of presence/absence of the encapsulant, and the gas component containing C is always released into the atmosphere in the crucible. If only the release of the C-component occurs, the C-concentration in the melt is decreased, and the influence of the variation of the initial C-concentration is expected to be suppressed.

It is assumed by the inventors of the present invention, that when the encapsulant is used, not only the release of the C-component from the melt of the GaAs polycrystal, but also the incorporation of the C-component into the melt occurs.

A specific amount of carbon-containing gas such as CO gas, etc., exists in the crucible even under the inert gas atmosphere. Such a CO gas, etc., is generated by a reaction between the graphite used for each kind of member in the high-pressure vessel such as the upper heaters, the lower heaters, and the susceptor, etc., and moisture (H₂O) and oxygen (O₂) remained in the high-pressure vessel. Further, as described above, the gas component of C released from the melt of the GaAs polycrystal is also added thereto. According to the inventors of the present invention, it can be considered that the encapsulant in the liquid state is intervened in the incorporation of the CO gas, etc., into the melt.

Specifically, it is considered that the generated CO gas, etc., is melted in the encapsulant such as B₂O₃, etc., and an oxidation-reduction reaction occurs between the CO gas and GaAs as shown in formulas (1) and (2), on the B₂O₃—GaAs melt interface between the encapsulant and the melt of the GaAs polycrystal. Ga and As are turned into Ga₂O₃ and As₂O₃ in the liquid of B₂O₃ as a result of the reaction with the CO gas melted in the encapsulant, on the B₂O₃—GaAs melt interface. C thus generated is incorporated into the melt of GaAs. According to the inventors of the present invention, such a reaction does not occur without intervening of the encapsulant, and almost no incorporation of the CO gas into the melt occurs.

Thus, when the GaAs polycrystal is heated and melted using the encapsulant, a final C-concentration in the melt of the GaAs polycrystal is determined by a balance of the incorporation of the CO gas in the crucible into the melt, and the release of the C-component from the melt. An amount of the CO gas, etc., generated from each kind of member in the high-pressure vessel is considered to be approximately constant. However, the concentration of C initially contained in the GaAs polycrystal is different in some cases, and it can be considered that a release amount of the C-component from the melt of the GaAs polycrystal and an incorporation amount of the released C-component are also increased or decreased accordingly. As a result, the final C-concentration in the melt depends on the C-concentration initially contained in the GaAs polycrystal, and it can be considered that under its influence, there is also the variation generated in the C-concentration in the produced GaAs single crystal. Further, by release and incorporation of the C-component, the C-concentration in the melt is changed before and after melting in some cases, and it can be considered that even if the C-component is added based on the initial C-concentration, C in the GaAs single crystal is deviated from the specific concentration.

In this embodiment, as being attempted by the inventors of the present invention as described above, first, the GaAs polycrystal is heated and melted without using the encapsulant 11. In this case, it can be considered that the incorporation of the GaAs polycrystal such as CO gas into the melt is suppressed, and the release of the C-component from the melt is exclusively occurs, to thereby reduce the C-concentration in the melt. Namely, the influence of the initially contained C is almost removed. In the incorporating step of the above-mentioned impurity element, the C-containing gas is introduced again in the above-mentioned state, and therefore C corresponding to the introduction amount is incorporated into the raw material 10m, and the specific C-concentration can be obtained. Further, the variation of the C-concentration is suppressed.

Further, in this embodiment, for example the inside of the crucible 23 is set in a range of the specific pressure. Such a pressure is not less than the steam pressure of As being the group V element for example, and is in a range of not more than the steam pressure of the gas component containing C being the impurity. Further, by covering the upper portion of the crucible 23 by the lid 27, such a pressure control is facilitated. Thus, the C-component can be released while suppressing the decomposition and the evaporation of As from the melt of the GaAs polycrystal, even if not using the encapsulant 11.

Further, according to this embodiment, the C-component is incorporated into the raw material 10m through the encapsulant 11 that covers the liquid surface of the raw material 10m in the introducing step of the impurity element-containing gas. The effect of incorporating the C-component by the encapsulant 11 is probably exhibited in this case as well. Therefore, the incorporation of the C-component into the raw material 10m can be accelerated.

As described above, the semiconductor single crystal 10 such as GaAs single crystal, etc., having the specific C-concentration can be precisely produced, irrespective of the C-concentration in the GaAs polycrystal being the raw material 10m. Thus, according to this embodiment, the method of producing the inexpensive and simple group III-V compound semiconductor single crystal is provided, which is capable of reusing the defective part, etc., containing the impurity for example. Further, waste of a toxic substance such as As, etc., can be reduced.

### OTHER EMBODIMENT OF THE PRESENT INVENTION

As described above, explanation is specifically given for the embodiment of the present invention. However, the present invention is not limited to the above-mentioned embodiment, and can be variously modified in a range not departing from the gist of the invention.

For example, in the above-mentioned embodiment, explanation is mainly given for the GaAs single crystal in which Ga is the group III element and As is the group V element. However, the contained element, etc., is not limited thereto. For example, indium (In) and aluminum (Al), etc., can be given as the group III element. Also, phosphor (P) and nitrogen (N), etc., can be given as the group V element. Thus, the group III-V compound semiconductor single crystal made of not only GaAs but also GaP, GaN, InAs, InP, AlGaInP, etc., can be produced.

Further, in the above-mentioned embodiment, the semi-insulating GaAs single crystal is produced, in which C is added for imparting semi-insulation property. However, the added impurity is not limited to C. Further, various impurities that control conductivity of the semiconductor such as imparting not only the semi-insulating property but also n-type or p-type conductivity, can be used.

Further, in the above-mentioned embodiment, the raw material 10m is produced using the polycrystallized defective part of the semiconductor single crystal produced by the LEC method. However, the whole part of the semiconductor crystal such as the part in which the concentration of the impurity is deviated from the specific value, and the part in which fracture or crack is generated, can be used. The semiconductor crystal, etc., produced by a method other than the LEC method may also be used.

Further, in the above-mentioned embodiment, the GaAs polycrystal being the raw material 10m is heated by covering the upper portion of the crucible 23 by the lid 27 in the producing step of the raw material 10m before adding the encapsulant 11. However, heating may be performed in a state that the upper portion of the crucible is opened. At this time, if the inside of the crucible is set to a specific pressure or more, the evaporation and separation of the group V element such as As, etc., can be suppressed.

Further, in the above-mentioned embodiment, the melt of the GaAs polycrystal is coagulated once in the producing step of the raw material 10m before adding the encapsulant 11. However, a step of heating the encapsulant, which is the next step, may be performed while not coagulating the melt of the GaAs polycrystal.

Further, in the above-mentioned embodiment, the same crucible 23 and the same semiconductor single crystal producing device 20 are used before/after adding the encapsulant 11. However, a different crucible and a different semiconductor single crystal producing device may be used before/after adding the encapsulant 11.

Further, in the above-mentioned embodiment, the crystal growth is caused while lifting the seed crystal 22s in the lifting step of the semiconductor single crystal 10. However, the crystal growth may be caused while lowering the crucible, with a position of the seed crystal fixed.

Further, in the above-mentioned embodiment, the crucible 23 and the lid 27 are made of PBN, etc. However, the material of them is not limited thereto. The crucible and the lid may be made of a different material respectively.

### Example

Next, an example of the present invention will be described, together with a comparative example.

First, the semi-insulating GaAs single crystal according to an example and a comparative example was fabricated. The GaAs polycrystal being the defective part which was polycrystallized at the time of production by the normal LEC method, was used in producing the raw material used for the semi-insulating GaAs single crystal. Note that C is contained in the GaAs polycrystal, with a specific concentration.

The semi-insulating GaAs single crystal of the example was fabricated by a similar procedure and method as those of the above-mentioned embodiment.

Specifically, the upper portion of the crucible was covered by the lid, and the GaAs polycrystal 35000 g was melted and coagulated. Next, the encapsulant 2500 g was added and melted, with the lid of the crucible removed, and the C-component was added by the CO gas. A target concentration at this time was set to 15×10¹⁵/cm³ or more and 35×10¹⁵/cm³ or less. The concentration of C contained in the GaAs polycrystal being the raw material was not taken into consideration, and in the normal LEC method, the introduction amount of the CO gas was adjusted so that the above-mentioned target concentration could be obtained, when Ga and As with high purity such as 6N (99.9999 mass %), etc., were used for example. Thereafter, the seed crystal in contact with the raw material was lifted, and the crystal growth was caused.

The semi-insulating GaAs single crystal of a comparative example was also fabricated by approximately the similar procedure and method as those of the above-mentioned example. However, in the comparative example, the encapsulant 2500 g was initially added, and the above-mentioned whole step was performed, with the upper portion of the crucible opened.

The steps of the example and the comparative example were respectively repeated, to thereby fabricate 10 (lots) of the semi-insulating GaAs single crystal of the example and the comparative example respectively.

Concentrations of C contained in the GaAs polycrystal being the raw material, and the semi-insulating GaAs single crystal of the example and the comparative example, were shown in the following table 1.

TABLE 1

| | Example | | Comparative example | |
|---|---|---|---|---|
| | Carbon con- | Carbon con- | Carbon con- | Carbon con- |
| | centration in | centration in | centration in | centration in |
| | raw material | grown single | raw material | grown single |
| | polycrystal | crystal | polycrystal | crystal |
| | (×10¹⁵/cm³) | (×10¹⁵/cm³) | (×10¹⁵/cm³) | (×10¹⁵/cm³) |
| Lot 01 | 42.6 | 25.8 | 24.6 | 37.2 |
| Lot 02 | 27.9 | 26.9 | 38.5 | 47.3 |
| Lot 03 | 19.6 | 25.3 | 29.9 | 38.9 |
| Lot 04 | 25.6 | 24.2 | 5.6 | 25.6 |
| Lot 05 | 9.2 | 26.4 | 22.1 | 35.8 |
| Lot 06 | 11.4 | 23.8 | 32.4 | 42.1 |
| Lot 07 | 33.2 | 24.9 | 22.6 | 36.7 |
| Lot 08 | 24.5 | 25.1 | 21.6 | 34.5 |
| Lot 09 | 5.3 | 28.2 | 8.7 | 27.2 |
| Lot 10 | 18.7 | 22.3 | 18.4 | 33.2 |

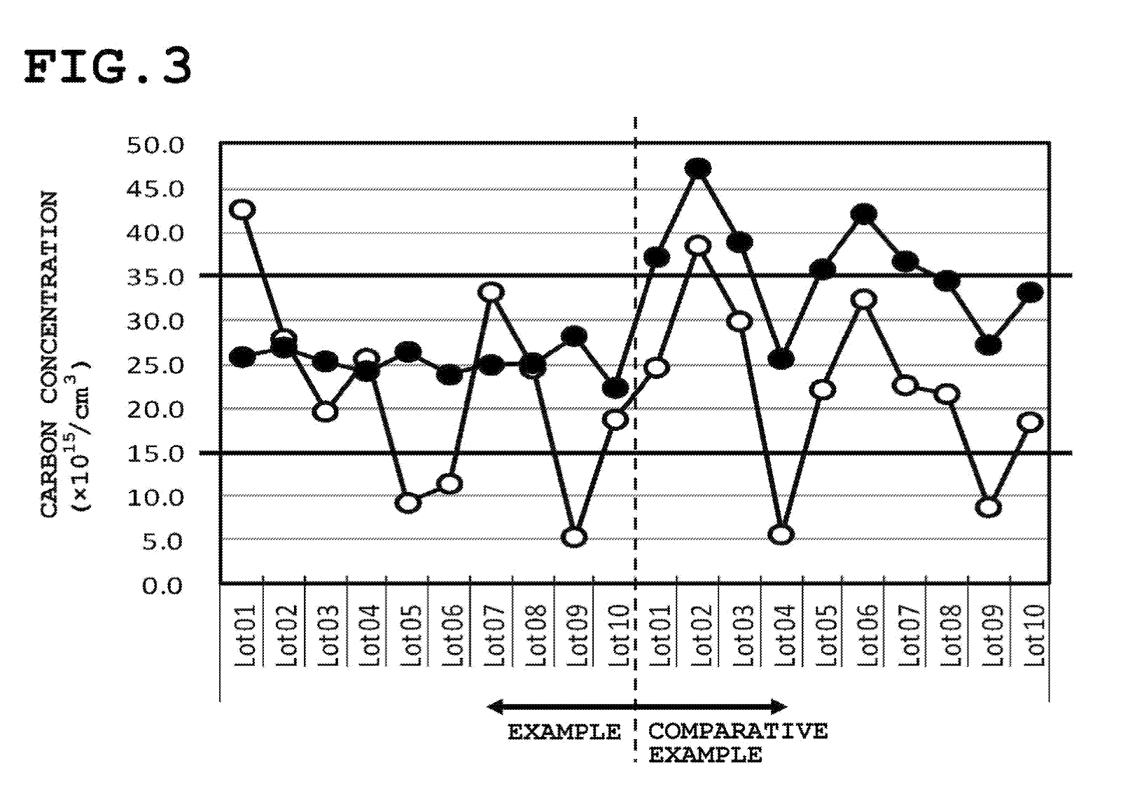

Further, FIG. 3 graphically shows numerical values in table 1. FIG. 3 is a graph showing the carbon concentration in each lot of the semi-insulating GaAs single crystal of the example and the comparative example. The horizontal axis of the graph indicates the lots 1 to 10 of the example and the comparative example, and the vertical axis of the graph indicates the carbon concentration (×10¹⁵/cm³) in each crystal. Further, the concentrations of C contained in the semi-insulating GaAs of the example and the comparative example are indicated by , and the concentrations of C contained in the GaAs polycrystal being the raw material are indicated by ◯ₒ

As shown in FIG. 3 and the column of “carbon concentration in the raw material polycrystal” in table 1, there is a large variation in the C-concentration in the GaAs polycrystal being the raw material.

Meanwhile, as shown in the left side of the graph in FIG. 3 and the column of “carbon concentration in the grown single crystal” at the left side of table 1, the C-concentration in the semi-insulating GaAs single crystal of the example is set in the range of 15×10¹⁵/cm³ or more and 35×10¹⁵/cm³ or less being the target concentration, in all 10 lots. It can be considered that initially, by melting the GaAs polycrystal without using the encapsulant, the influence of the C-concentration in the GaAs polycrystal is reduced.

Meanwhile, as shown in the right side of the graph in FIG. 3 and the column of “carbon concentration in grown single crystal” at the right side of table 1, the C-concentration in the semi-insulating GaAs single crystal of the comparative example was deviated from the range of 15×10¹⁵/cm³ or more and 35×10¹⁵/cm³ or less being the target concentration, in 6 lots of the 10 lots. It can be considered that the influence of the C-concentration in the GaAs polycrystal is received, because the GaAs polycrystal is melted using the encapsulant initially. The C-concentration in the actually obtained semi-insulating GaAs single crystal becomes higher as a whole relatively to the target concentration, and therefore it can be considered that the reduction of the C-concentration is not achieved, under the influence of the re-incorporation of the C-component.

What is claimed is:

1. A method of producing a group III-V compound semiconductor single crystal, using a Liquid Encapsulated Czochralski method, comprising:
producing a raw material by housing a group III-V compound semiconductor crystal containing group III element and group V element and an impurity in a crucible, and heating and melting the group III-V compound semiconductor crystal in a state that a surface of the group III-V compound semiconductor crystal to an atmosphere in the crucible;
growing the group III-V compound semiconductor single crystal by heating the raw material and an encapsulant by adding the encapsulant into the crucible in which the raw material is housed, and making a seed crystal in contact with a melt of the raw material with a liquid surface covered by the encapsulant in a liquid state, and lifting the seed crystal.

2. The method of claim 1, wherein in producing the raw material, an inside of the crucible is set in an inert gas atmosphere of not less than a steam pressure of the group V element and not more than the steam pressure of a gas component containing the impurity.

3. The method of claim 1, wherein in producing the raw material, an inside of the crucible is set in an inert gas atmosphere of a pressure of 5 MPa or more and 8 MPa or less.

4. The method of claim 2, wherein in producing the raw material, an inside of the crucible is set in an inert gas atmosphere of a pressure of 5 MPa or more and 8 MPa or less.

5. The method of claim 1, wherein in producing the raw material, an upper portion of the crucible is covered by a lid.

6. The method of claim 2, wherein in producing the raw material, an upper portion of the crucible is covered by a lid.

7. The method of claim 3, wherein in producing the raw material, an upper portion of the crucible is covered by a lid.

8. The method of claim 1, wherein the impurity is composed of an element that controls conductivity of a group III-V compound semiconductor.

9. The method of claim 2, wherein the impurity is composed of an element that controls conductivity of a group III-V compound semiconductor.

10. The method of claim 3, wherein the impurity is composed of an element that controls conductivity of a group III-V compound semiconductor.

11. The method of claim 5, wherein the impurity is composed of an element that controls conductivity of a group III-V compound semiconductor.

12. The method of claim 1, wherein the impurity is C.

13. The method of claim 2, wherein the impurity is C.

14. The method of claim 3, wherein the impurity is C.

15. The method of claim 5, wherein the impurity is C.

16. The method of claim 8, wherein the impurity is C.

17. The method of claim 1, wherein in growing the group III-V compound semiconductor single crystal,
an impurity of the same kind as the above impurity is incorporated into the raw material through the encapsulant that covers a liquid surface of the raw material, to thereby grow a semi-insulating group III-V compound semiconductor single crystal containing the impurity, and
when incorporating the impurity into the raw material,
incorporation of the impurity into the raw material is accelerated by the encapsulant.

18. The method of claim 2, wherein in growing the group III-V compound semiconductor single crystal,
an impurity of the same kind as the above impurity is incorporated into the raw material through the encapsulant that covers a liquid surface of the raw material, to thereby grow the semi-insulating group III-V compound semiconductor single crystal containing the impurity, and
when incorporating the impurity into the raw material,
incorporation of the impurity into the raw material is accelerated by the encapsulant.

19. The method of claim 3, wherein in growing the group III-V compound semiconductor single crystal,
an impurity of the same kind as the above impurity is incorporated into the raw material through the encapsulant that covers a liquid surface of the raw material, to thereby grow the semi-insulating group III-V compound semiconductor single crystal containing the impurity, and
when incorporating the impurity into the raw material,
incorporation of the impurity into the raw material is accelerated by the encapsulant.

20. The method of claim 1, wherein the group III element is at least any one of Ga, In, and Al, and the group V element is at least any one of As, P, and N.
